(19) United States
(12) Patent Application Publication
(10) Pub. No.: US 2010/0038283 A1
(43) Pub. Date: Feb. 18, 2010

(54) Wafer container having the latch and inflatable seal element

(76) Inventors: Ming-Long CHIU, Shulin City (TW); Kuo-Chun Hung, Shulin City (TW)

Correspondence Address: SINORICA, LLC, 2275 Research Blvd., Suite 500, ROCKVILLE, MD, 20850, US

(21) Appl. No.: 12/234,650

(22) Filed: Sep. 20, 2008

(30) Foreign Application Priority Data
Aug. 14, 2008 (TW) 097130941

(51) Int. Cl. H01L 21/673

(52) U.S. Cl. 206/711; 220/324

(57) ABSTRACT

A wafer container includes a container body that having an open front on sidewall, a plurality of slots disposed in the container body for support wafers, and a door is assembled with opening of the container body for protecting the wafer therein, the characteristic in that: at least one latch is disposed in the door and an inflatable seal element is located at the rim of the inner side of the door.

### BACKGROUND OF THE INVENTION

1. Field of the Invention

The present field of the invention is related to a wafer container, and more particularly, to a wafer container with a latch component disposed in the door and with an inflatable seal element located in the inner surface of the door.

2. Description of the Prior Art

The semiconductor wafers are transferred to different stations to apply the various processes in the required equipments. A sealed container is provided for automatic transfer to prevent the pollution from occurring during transferring process. FIG. 1 shows the views of wafer container of the conventional prior art. The wafer container is a front opening unified pod (FOUP) which includes a container body 10 and a door 20. The container body 10 is disposed with a plurality of slots 11 for horizontally placing a plurality of wafers, and an opening 12 is located on a sidewall of the container body 10 for importing and exporting. Further, the door 20 includes an outer surface 21 and an inner surface 22, in which the door 20 is joined with the opening 12 of the container body 10 via inner surface 22 to protect the plurality of wafers within the container body 10. Furthermore, at least one latch hole 23 is disposed on the outer surface 21 of the door 20 for opening or closing the wafer container. According to the aforementioned, due to that the wafer is placed in the container body 10 horizontally, thus, the FOUP needs a wafer restraint component to prevent the wafer from displacement or from movement toward the opening 12 of container body 10 occurring during the wafer transportation due to vibration.

FIG. 2 is a view of a front opening unified pod (FOUP) as described in U.S. Pat. No. 6,736,268. As shown in FIG. 2, the inner surface 22 of the door 20 is disposed with a recess 24 and the recess 24 is extended from the top 221 of the inner surface 22 to the bottom 222, and is located between two latch components 230 (inside of the door 20). A wafer restraint module (not shown in Figure) is further disposed in the recess 24. The wafer restraint module consists two wafer restraint components 100, and each wafer restraint component 100 includes a plurality of wafer contact heads 110 to sustain corresponding wafers, so as to prevent the wafer from displacement or movement toward the door opening due to vibration occurring in the wafer transportation procedure. However, the above-mentioned wafer restraint module is disposed on the recess 24 of the inner surface 22 of the door 20, and the wafer is merely attached to the inner surface 22 of the door 20 or the wafer is partially settled down within the recess 24. The wafers either sit adjacent to the inner surface 22 of the door 20 or only slightly enter into the recess 24. As a result, the wafers are not securely and fully settled into the recess 24 in order to effectively shorten the length between the front side and the back side of the FOUP. In addition, the tiny dust particles generated due to the friction between the wafer restraint module and the wafers can be easily accumulated in the recess 24. In the process of cleaning the accumulated dust particles, it is necessary to separate the wafer restraint module from the recess 24 on the inner surface 22 of the door 20. By frequent separation and assembly of the wafer restraint module in order to apply the cleaning process, the wafer restraint module is easily slackened.

Furthermore, FIG. 3 is a view of latch component 230 in door 20 of a front opening unified pod (FOUP) as described in U.S. Pat. No. 5,711,427. The method for assembling door 20 and container body 10 is mainly to dispose movable bolts 231 on the two sides of door 20 (namely between outer surface 21 and inner surface 22) and to dispose socket holes (not shown in Figure) near the edge of opening of door 10 for corresponding to bolts 231. The objective of fixing door 20 in the container body 10 can thus be achieved with the turning of latch hole disposed on outer surface 21 of door 20 and the inserting of latch bolts 231 into socket holes, wherein the insertion and withdrawal of bolts 231 is controlled by the turning of latch hole via a round-shaped cam 232.

And in the operating practice of semiconductor factory, the opening of FOUP is mainly operated through a wafer carrying apparatus (not shown in Figure). The wafer carrying apparatus includes at least one opening latch (not shown in Figure) that is to be inserted into the latch hole 23 on outer surface 21 of door 20 of the FOUP and to rotate cam 232 to drive the movable bolts 231 to open or close the FOUP.

In addition, other U.S. patents that describe latch component in door of FOUP include U.S. Pat. No. 5,915,562, U.S. Pat. No. 5,957,292, U.S. Pat. No. 6,622,883, and U.S. Pat. No. 6,902,063. In order to achieve air tightness when joining door and container body, movable bolts will shift longitudinally for fastening a springy seal element, which leads to achievement of both objectives of closing FOUP and air tightness. However, in prior latch patents, complex mechanic apparatuses are used, which not only results in higher failure rate but also generates too much mechanical friction in the operating process that pollutes wafers. Moreover, the air tightness achieved by fastening springy seal element with shift of movable bolts cannot maintain for very long time and is not effective enough.

Moreover, in conventional FOUP, some restraint components are disposed on the inner surface of door 20. Thus when door 20 closes container body 10, the restraint components contact wafers and completely fix the wafers in order to prevent displacement of wafers in FOUP from happening during transportation procedure. And in order to avoid too forcible collision or friction between restraint components and wafers when contacting, therefore, as shown in FIG. 4, a few U.S. patents disclose springy element 86 that is disposed between cam 232 in latch component 230 and door 20. In the process in which cam 232 rotates and drives movable bolts 231 to close FOUP, this springy element 86 can function as damping for restraint component disposed on inner surface of door 20 to contact wafers under mitigated and smooth condition, and thus the problem of collision and friction can be solved. These U.S. patents include U.S. Pat. No. 6,880,718, U.S. Pat. No. 7,168,587, and U.S. Pat. No. 7,182,203. However, this way of laterally driving, it is easy for an offsetting force to generate on the moving direction of movable bolts 231, causing failure of insertion of movable bolts into socket holes of container body 10. Thus, container body 10 and door 20 cannot be closed, and the production cost of FOUP is also increased.

### SUMMARY OF THE INVENTION

In the latch component of the door of front opening unified pod (FOUP) of prior art, the springy seal element is fastened by the shift of movable bolts, which easily causes gas leakage and thus air tightness cannot be maintained for very long time. One objective of the present invention is thus to provide a front opening unified pod (FOUP) with its door disposed with an inflatable seal element. When the door latch locks the door with the container body, a condition of air tightness can be achieved by purging the inflatable seal element for isolating wafers in the wafer container from external atmosphere.

Another objective of the present invention is to provide a front opening unified pod (FOUP) with its container body disposed with at least a purgation valve for forming positive pressure inside the container body and thus preventing external atmosphere from entering the wafer container and reducing pollution of wafers.

Still another objective of the present invention is to provide a front opening unified pod (FOUP) with its door disposed with latch component with at least an oval cam, wherein with the design of roller, the moving bars can be driven by the oval cam to move to and fro on only one plane surface, the design of which reduces friction generated in the moving process of moving bars and also reduces pollution.

Still another objective of the present invention is to provide a front opening unified pod (FOUP) disposed with latch component with oval cam, wherein a recess is formed between latch component for wafers to be fully and effectively filled in the space of the recess. This makes it possible for the length between the front side and the back side of the FOUP to be shortened, and also for the center of gravity to be more focused on the central part of wafer container to make the wafer container more stable.

Yet another objective of the present invention is to provide a front opening unified pod (FOUP) disposed with latch component with oval cam, wherein wafer restraint component can be disposed on inner surface of the door for effectively fixing the wafers.

According to above objectives, the present invention provides a front opening unified pod (FOUP), which includes a container body and a door. A plurality of slots are disposed in the container body for supporting a plurality of wafers, and an opening is formed on one sidewall of the container body for importing and exporting the plurality of wafers. The door includes an outer surface and an inner surface; the door joins with the opening of container body via its inner surface for protecting the plurality of wafers in the container body. The characteristic of front opening unified pod (FOUP) in that: at least a latch component is disposed in the door and an inflatable seal element is disposed around the rim of the inner surface of the door.

The present invention further provides a front opening unified pod (FOUP) with a container body and a door. A plurality of slots are disposed in the container body for supporting a plurality of wafers, and an opening is formed on one sidewall of the container body for importing and exporting of the plurality of wafers. The door includes an outer surface and an inner surface; the door joins with the opening of container body via its inner surface for protecting the plurality of wafers in the container body. The characteristic of front opening unified pod (FOUP) in that: at least a purgation valve is disposed on the container body, at least a latch component is disposed in the door, and an inflatable seal element is disposed around the rim of the inner surface of the door.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

The foregoing aspects and many of the attendant advantages of this invention will become more readily appreciated as the same becomes better understood by reference to the following detailed description, when taken in conjunction with the accompanying drawings, wherein:

FIG. 1 is a view of the front opening unified pod (FOUP) of the prior art;

FIG. 2 is a view of the door of the front opening unified pod (FOUP) of the prior art;

FIG. 3 is a view of another door of front opening unified pod (FOUP) of the prior art;

FIG. 4 is a view of still another door of front opening unified pod (FOUP) of the prior art;

FIG. 5 is a view of the door of a front opening unified pod (FOUP) of the present invention;

FIG. 6 is a magnified view of part of the latch component in FIG. 5 of the present invention;

FIG. 7A to FIG. 7C are magnified views of the moving bars of the latch component of the present invention;

FIG. 8 is a view of the latch component of the present invention in closing status;

FIG. 9 is a view of a front opening unified pod (FOUP) of the present invention;

FIG. 10 is a view of the wafer restraint module of a front opening unified pod (FOUP) of the present invention;

FIG. 11 is a view of the wafer restraint module of a front opening unified pod (FOUP) of the present invention being fixed on the door;

FIG. 12 is a view of the wafer restraint module of a front opening unified pod (FOUP) of the present invention in the process of restricting the wafer;

FIG. 13A is a view of the left and right wafer restraint modules of a front opening unified pod (FOUP) of the present invention being an integrated structure;

FIG. 13B is a view of the left and right wafer restraint modules of a front opening unified pod (FOUP) of the present invention being an integrated structure fixed on the door;

FIG. 14 is a view of another front opening unified pod (FOUP) of the present invention;

FIG. 15 is a view of the wafer restraint module of another front opening unified pod (FOUP) of the present invention;

FIG. 16A is a view of the wafer restraint module of another front opening unified pod (FOUP) of the present invention starting to contact the wafer;

FIG. 16B is a view of the wafer restraint module of another front opening unified pod (FOUP) of the present invention in the process of restricting the wafer;

FIG. 17 is a view of still another front opening unified pod (FOUP) of the present invention;

FIG. 18 is a view of the wafer restraint module of still another front opening unified pod (FOUP) of the present invention;

FIG. 19A is a view of the wafer restraint module of still another front opening unified pod (FOUP) of the present invention not contacting the wafer;

FIG. 19B is a view of the wafer restraint module of still another front opening unified pod (FOUP) of the present invention in the process of restricting the wafer;

FIG. 20 is a top view of a seal element disposed in the inner surface of the door of the present invention;

FIG. 21A and FIG. 21B are cross-sectional views of part of a sealing design front opening unified pod (FOUP) of the present invention before and after air tightness is achieved;

FIG. 22A and FIG. 22B are sectional views of part of another sealing design of front opening unified pod (FOUP) of the present invention before and after air tightness is achieved;

FIG. 23A and FIG. 23B are sectional views of part of still another sealing design of front opening unified pod (FOUP) of the present invention before and after air tightness is achieved; and

FIG. 24 is a cross-sectional view of the front opening unified pod (FOUP) of the present invention when the door is closed and the seal element is purged.

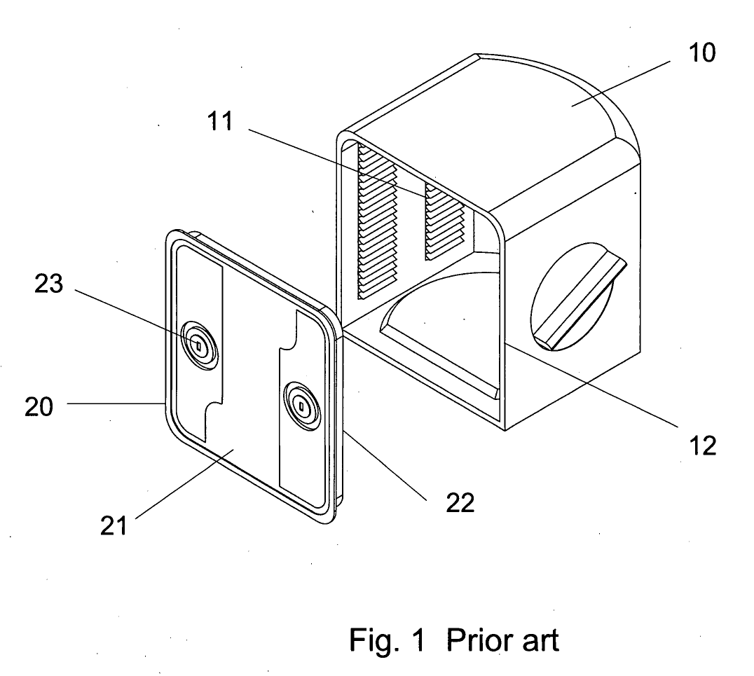

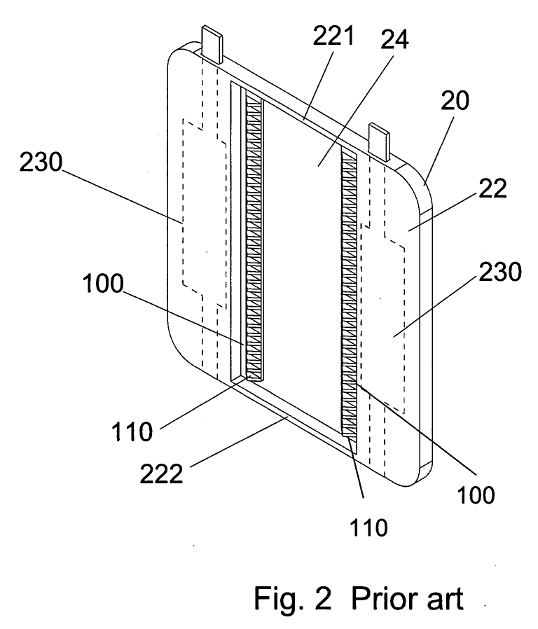

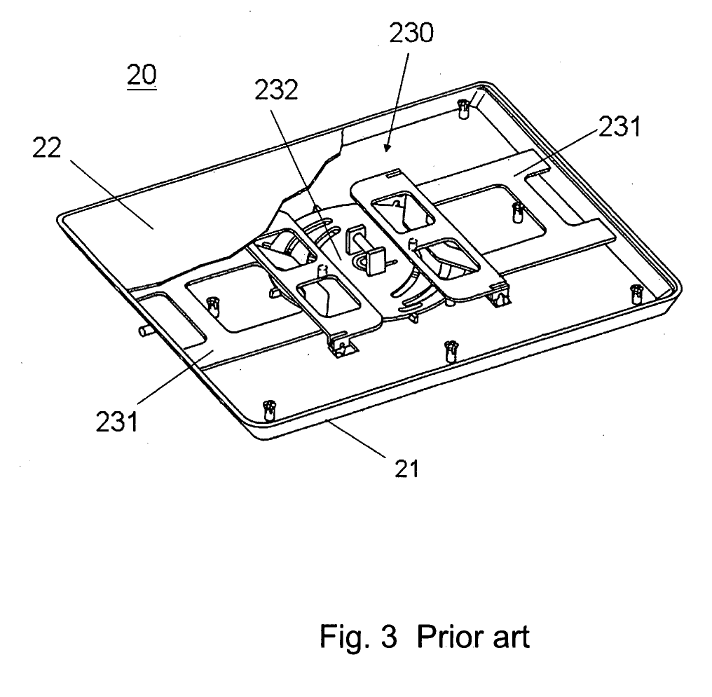

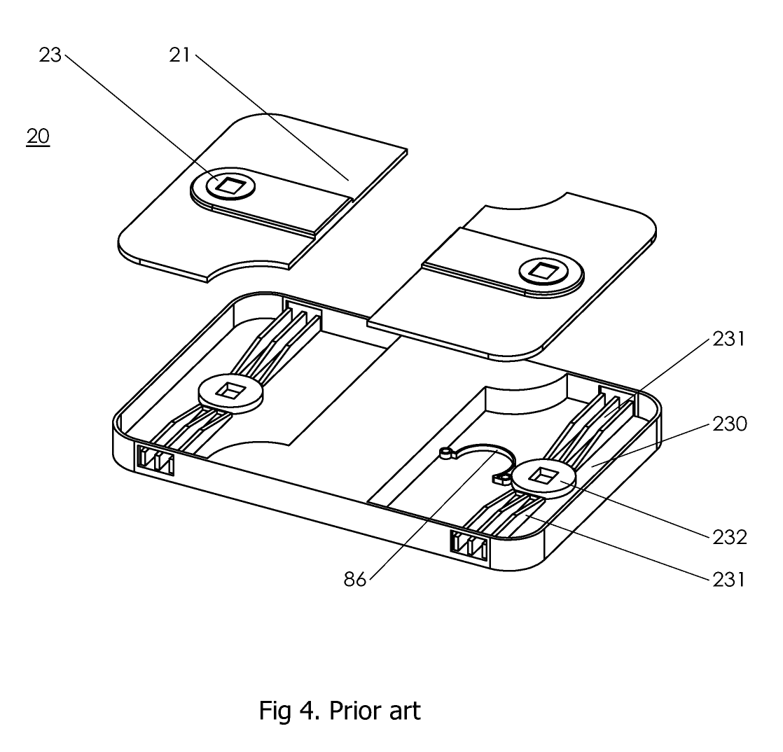

### DESCRIPTION OF THE PREFERRED EMBODIMENT

In order to disclose the skills applied in, the objectives of, and the effects achieved by the present invention in a more complete and clearer manner, preferred embodiments are herein described below in detail with related drawings disclosed for reference.

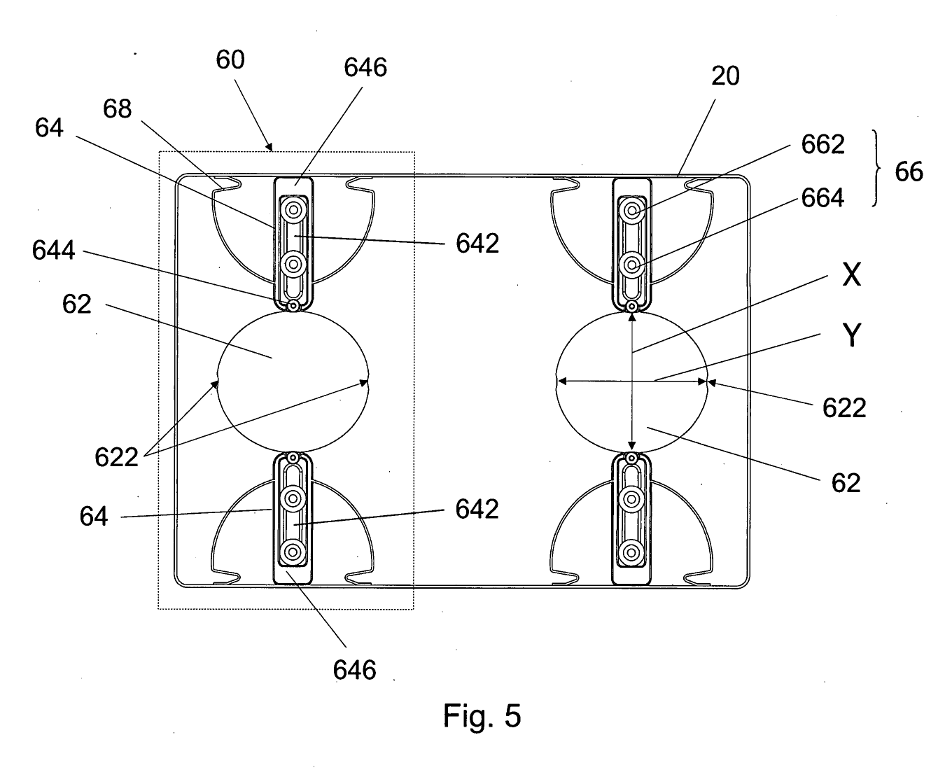

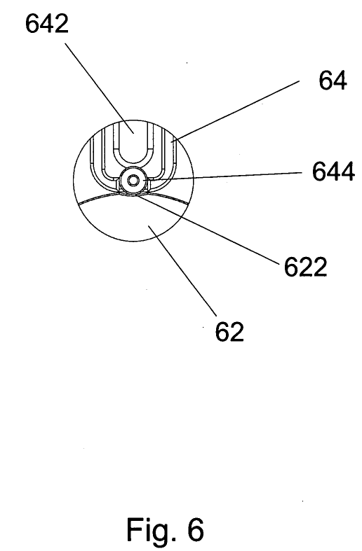

Referring to FIG. 5, which is a top view of latch component 60 in door 20 of front opening unified pod (FOUP) of the present invention. As shown in FIG. 5, a pair of latch components 60 is located between outer surface and inner surface of door 20, wherein each latch component 60 is composed of an oval cam 62, a pair of moving bars 64 contacting two ends of oval cam 62, at least one roller 66 disposed between outer surface and inner surface of door 20 and fixed in slide groove 642 of the moving bars 64, and a locating spring 68 being an integral part of the moving bars 64. Then referring to FIG. 6, which is a magnified view of two ends of oval cam 62 that contact moving bars 64. As shown in FIG. 6, in a preferred embodiment of the present invention, a locating roller 644 can be further disposed where moving bars 64 contacting two ends of oval cam 62. When oval cam 62 rotates, the force of friction between moving bars 64 and oval cam 62 can be reduced. Moreover, with the design of a plurality of locating grooves 622 on oval cam 62, when the oval cam 62 rotates, locating rollers 644 can slide smoothly into locating groove 622 as point of restriction for the rotating oval cam 62. In this preferred embodiment of the present invention, the oval cam 62 can be made of metal or polymer plastic material, which is not limited in the present invention.

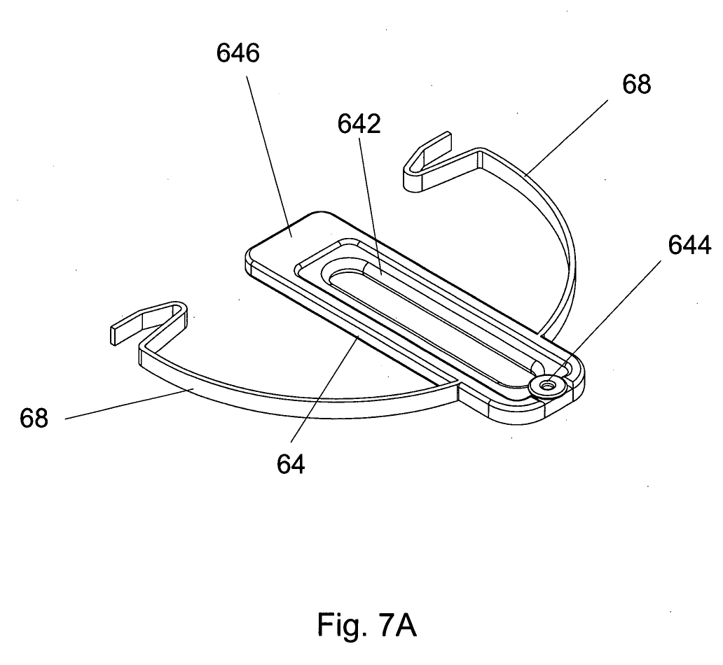

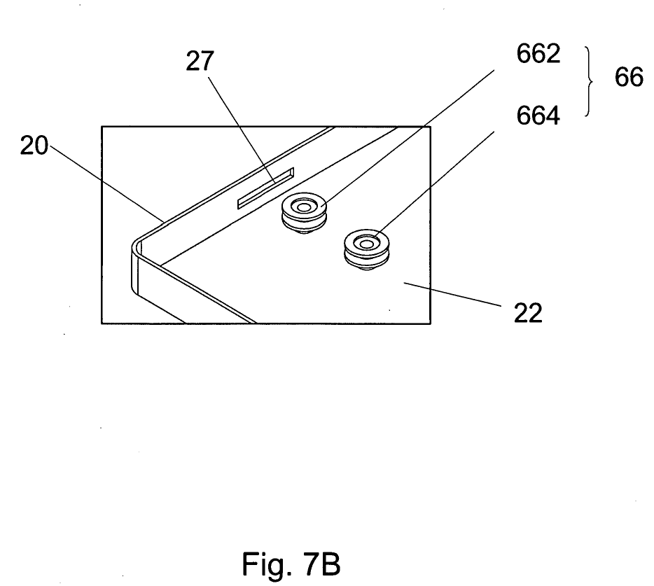

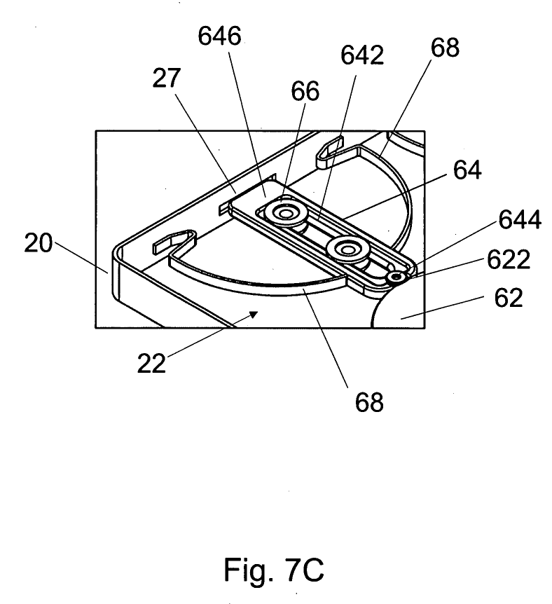

In the following, referring to FIGS. 7A-7C, which are views of moving bars 64 of latch component 60 of the present invention. On one end of moving bars 64 is disposed with a locating roller 644, and on the opposite end is a physical plane surface 646. Between the two ends a slide groove 642 is formed with roller 66 fastened in door 20 fixed in it. Moreover, the end of moving bars 64 that is near to locating rollers 644 is connected with one end of locating spring 68, and the other end of locating spring 68 is fixed on door 20. Therefore when door 20 is to close the opening 12 of container body 10, door 20 and container body 10 are first joined and then oval cam 62 is rotated; when oval cam 62 rotates, moving bars 64 are pushed by oval cam 62 toward the edge of door 20. Thus physical plane surface 646 of moving bars 64 is allowed to go through latch hole 27 of door 20 and extends into socket hole (not shown in Figure) located near the edge of opening of container body 10 and corresponding with latch hole 27, and container body 10 and door 20 can thus be joined into one and the closing procedure of container body 10 is thus completed. Meanwhile, locating spring 68 is compressed, and thus when door 20 is about to be opened, with the rotating of oval cam 62, a force of locating spring 64 generated according to Hooke's law will also drive moving bars 64 to resume to the location in opening status. In preferred embodiment of the present invention, moving bars 64 and locating spring 68 can be made of metal or polymer plastic material, which is not limited in the present invention; the material of roller 66 is not limited either in the present invention.

Moreover, as shown in FIG. 7B, in a preferred embodiment, rollers 66 are disposed in pair in door 20 and each of the pair of rollers is at a proper distance from the other. Therefore, when roller 662 and roller 664 are fixed in slide groove 642 of moving bars 64, this pair of rollers 66 can accurately and smoothly guide plane surface 646 of moving bars 64 through latch hole 27 located on door 20.

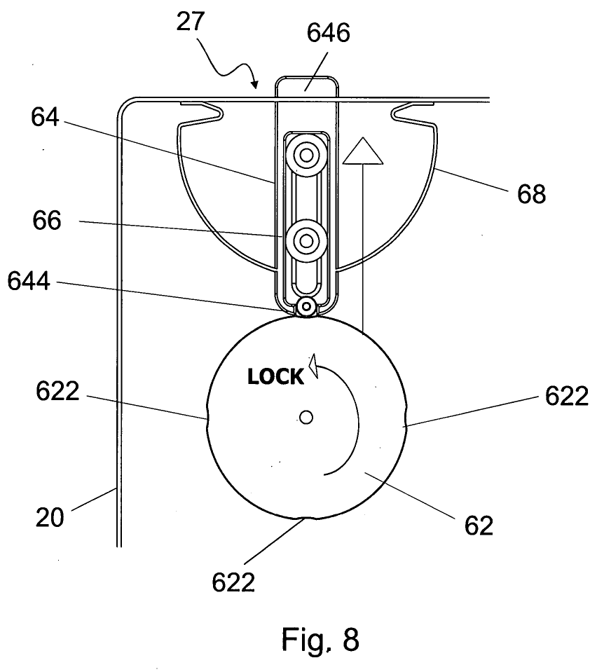

What is to be emphasized here is that, in the process of the present invention described above, an oval cam 62 and moving bars 64 are used to describe the operating procedures of latch component 60, but actually each oval cam 62 is in contact with a pair of moving bars 64, and in each door 20 is disposed with a pair of latch component 60 (as shown in FIG. 5, in which door 20 of the present invention is in opening status). Due to that the cam in latch component 60 of the present invention is an oval cam 62, this oval cam 62 forms a pair of latch holes (not shown in Figure) on the outer surface 21 of door 20. Since oval cam 62 has a longer radius Y and a shorter radius X in the present invention the difference between two different radiuses of oval cam 62 is used as starting component for controlling the to and fro movement of moving bars 64. For example, for moving bars 64 to move up or down along two lateral sides of door 20 for 10 mm˜30 mm in order to let front end of moving bars 64 go through door 20, the length difference between longer radius and shorter radius of oval cam 62 should be no less than 10 mm˜30 mm. Due to that the two ends of shorter radius of oval cam 62 are in contact with a pair of moving bars 64 located on two ends when door 20 opens, apparently, when door 20 closes container body 10, the moving bars 64 on two ends can be made to contact longer radius of oval cam 62 by turning oval cam 62. Since the different in length between longer radius and shorter radius of oval cam 62 should be no less than 50 mm, therefore when oval cam 62 turns to a locating groove 622 located on longer radius Y, front plane surface 646 of moving bars 64 can be made to go through latch hole 27 on door 20, as shown in FIG. 8. What is to be emphasized here is that as moving bars 64 are connected to one end of locating spring 68 near the end of locating roller 644, and the other end of locating spring 68 is fixed to door 20, therefore when oval cam 62 turns to locating groove 622 located on longer radius Y, moving bars 64 will be pushed by oval cam 62 toward latch hole 27 on the edge of door 20. At this time, locating spring 68 will be compressed, and thus when door 20 is about to be opened, with oval cam 62 turning to locating groove 622 located on shorter radius X, a force generated according to Hooke's law of locating spring 68 will also drive moving bars 64 to resume to the location in opening status (i.e. oval cam 62 stays at locating groove 622 located on shorter radius X).

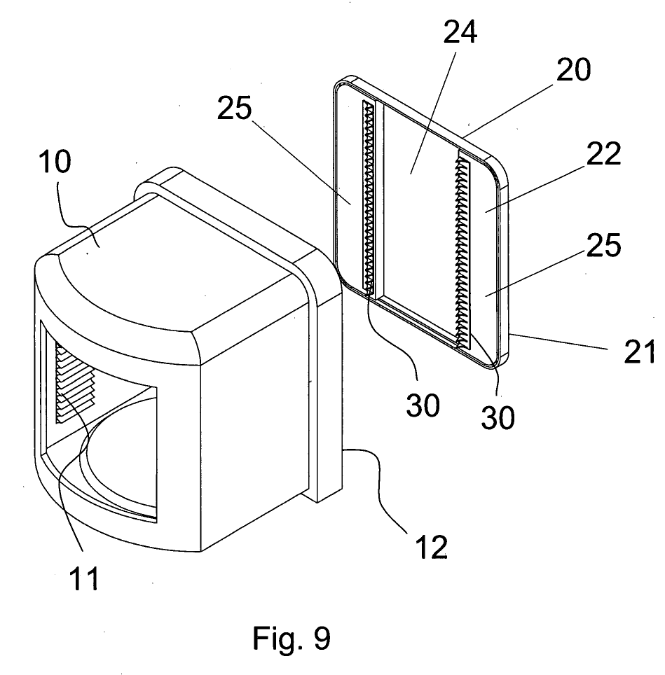

Then, referring to FIG. 9, which is a view of a wafer container of the present invention. This wafer container is a front opening unified pod (FOUP) which includes a container body 10 and a door 20. A plurality of slots 11 are disposed in the container body 10 for sustaining a plurality of wafers, and an opening 12 is formed on one sidewall of the container body 10 for importing and exporting the plurality of wafers. The door 20 includes an outer surface 21 and an inner surface 22. The outer surface 21 of door 20 is disposed with at least one latch hole (not shown in Figure) for opening or closing the front opening unified pod (FOUP). And around the center of inner surface 22 of door 20 is disposed with a recess 24. The recess 24 is between two platforms 25 and inside two platforms 25 is disposed with aforementioned latch component 60. An objective of the recess 24 is to sustain the plurality of wafers in container body 10 for shortening the length between the front side and the back side of the FOUP. And a wafer restraint module 30 is disposed on each of the platform 25 respectively for restricting the movement of wafers toward the opening of the wafer container and controlling the number of wafers settling down the recess 24.

The length of the recess 24 of the inner surface 22 of door 20 as described above is related to the distance between slots 11 in container body 10 and the number of the wafers. The distance between 12″ wafers has been a standard regulation in the industry to achieve maximum capacity of loading and ensure at the same time that there is enough space for the mechanical arm to stretch in for importing or exporting. In general, the number of wafers to be in the wafer container is 25 pieces. However, the width and the depth of recess 24 of the present invention can be adjusted. When the thickness of the door 20 is constant, the depth of recess 24 can be adjusted to be deeper, and the width of recess 24 is also adjusted to be wider for the whole wafer to be placed further into recess 24.

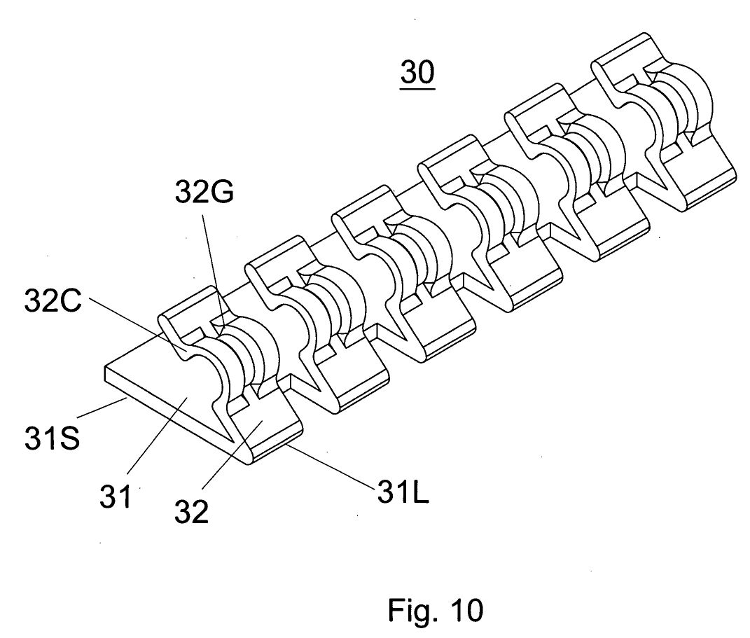

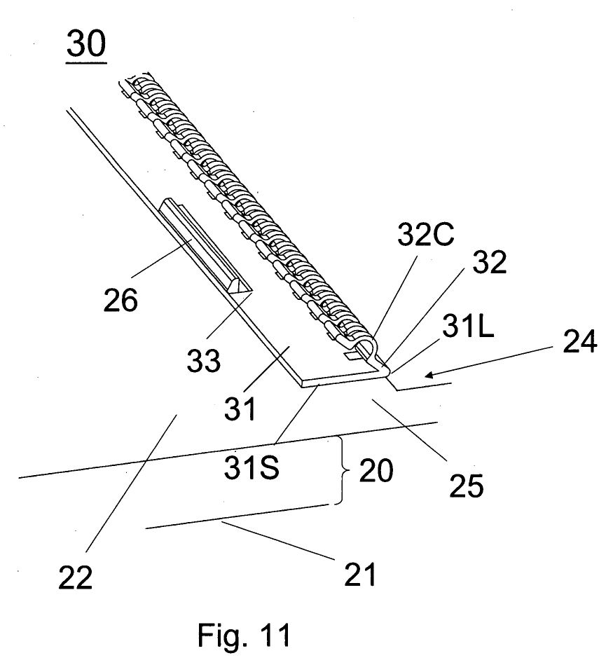

Moreover, referring to FIG. 10 and FIG. 11, which are views of wafer restraint module of wafer container of the present invention that is fixed to the door. The wafer restraint module 30 includes a rectangular bar base portion 31, which includes two longer sides 31L and two shorter sides 31S. One of the two longer sides 31L is adjacent to the recess 24 to form a plurality of curve portions 32 with a space at interval. A semicircle-like protruding portion 32C is formed between each curve portion 32 and its free-end. And a guide notch 32G is disposed on semicircle-like protruding portion 32C to contact wafers for restricting movement of corresponding wafers toward the opening of the wafer container.

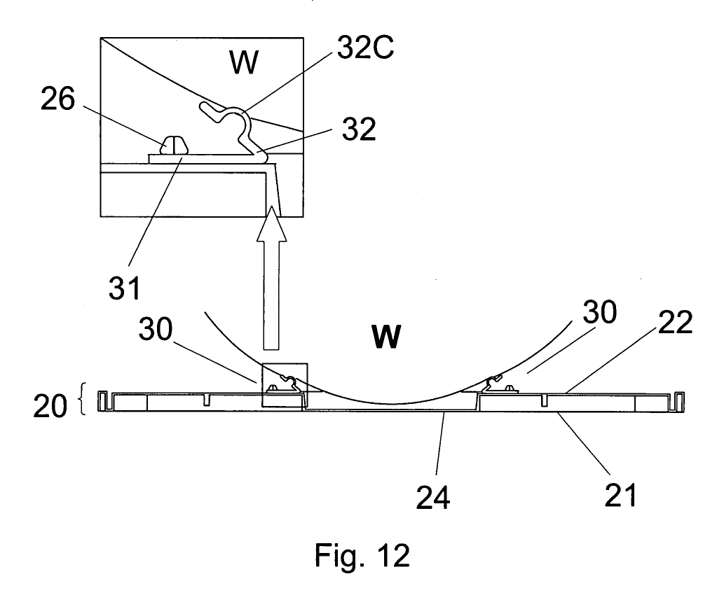

The guide notch 32G of the semicircle-like protruding portion 32C is used to sustain the wafer. The width of the guide notch 32G can be equaled to the thickness of wafer so that the wafer can sink into the guide notch 32G without moving up and down. The surface of guide notch 32G that contacts wafer can be coated with a wear-resisting material, such as PEEK material, to reduce the friction for the wafer. Furthermore, the wafer restraint module 30 can be an integrated structure and can be made of one or two different materials. For example, the base portion 31 and the curve portion 32 are made of one material and the semicircle-like protruding portion 32C is made of another material and formed on the curve portion 32. Obviously, an angle, which is about 10 to 60 degrees, is formed between the rectangular bar base portion 31 and the curve portion 32. Since the wafer restraint module 30 on two sides of recess 24 are symmetrical, the resultant forces is formed toward the center of the wafer when the wafer is restricted by wafer restraint module 30 (as shown in FIG. 12) for preventing the wafer from shaking. And the wafer restraint module 30 not only restricts the movement of wafer toward the opening of the wafer container, but also makes the wafer fully sink into the recess 24, so that the length between front side and of back side can be shortened, the center of gravity of the whole wafer container is more focused on the center of wafer container, and the stability of wafer container is also improved. As shown in FIG. 10, as a gap is located between the plurality of semicircle-like protruding portion 32C on the curve portion 32, thus the curve portion 32 is more elastic to permit deformation due to crackdown of the wafer.

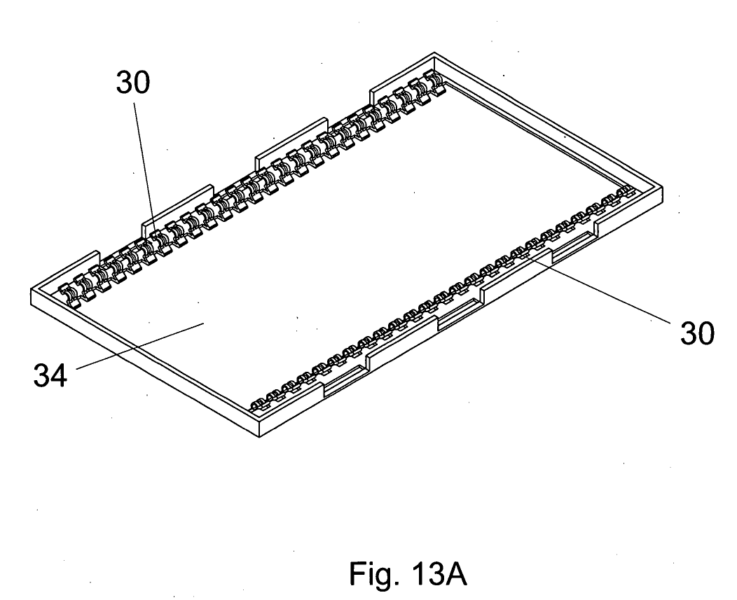

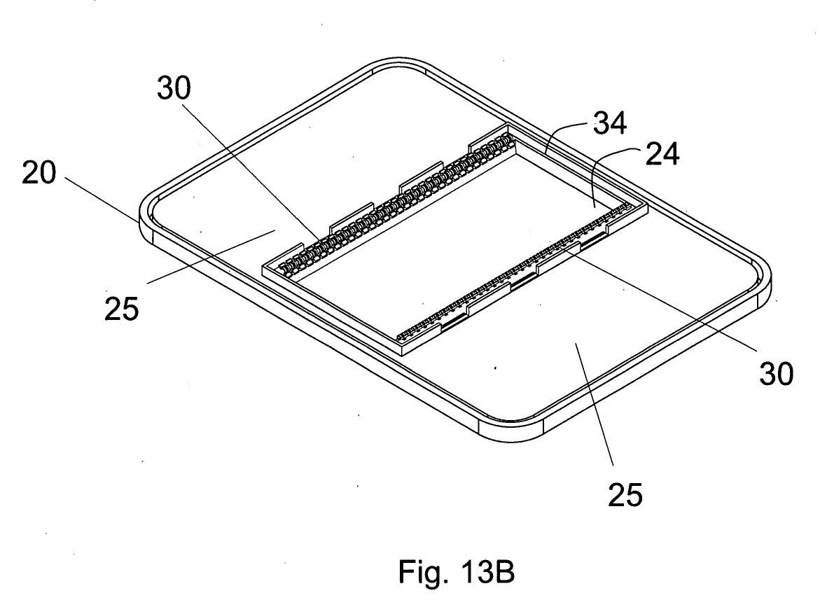

Furthermore, according to FIG. 11 and FIG. 12, the base portion 31 includes a plurality of snap holes 33, and a snap pillar 26 is disposed on the inner surface 22 that corresponds to the snap holes 33; thus, the wafer restraint module 30 is firmly set on the platforms 25 of the recess 24 of the inner surface 22 of the door 20 by snapping on the platforms 25. In order to facilitate the manufacturing procedures, the wafer restraint module 30 can also be integrated with the inner surface 22 of door 20 to prevent from slackening of the wafer restraint module 30. Then, referring to FIG. 13A and FIG. 13B, the wafer restraint module 30 on two sides of recess 24 can also be an integrated structure, which includes a central hole 34 that corresponds to the recess 24 of door 20. This integrated structure can also be firmly set on the inner surface 22 of door 20 by snapping on or directly integrated with the inner surface 22 of the door 20.

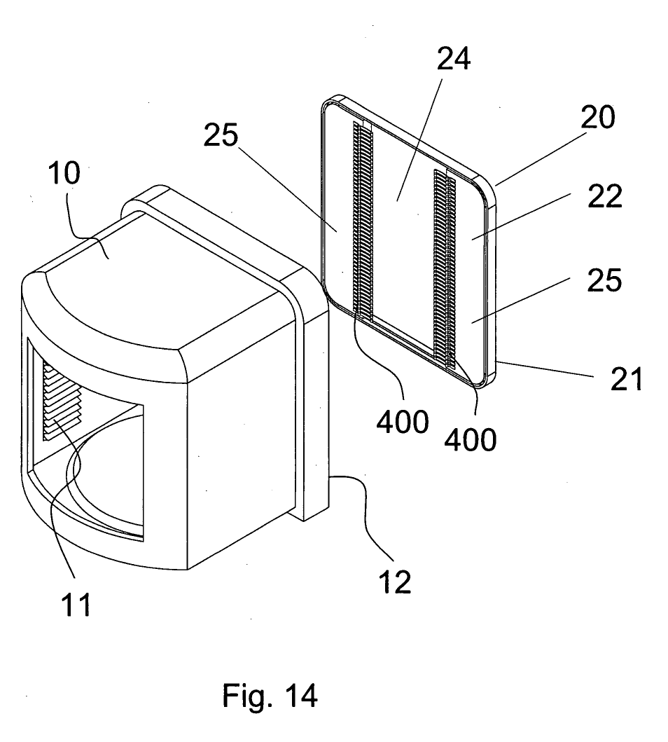

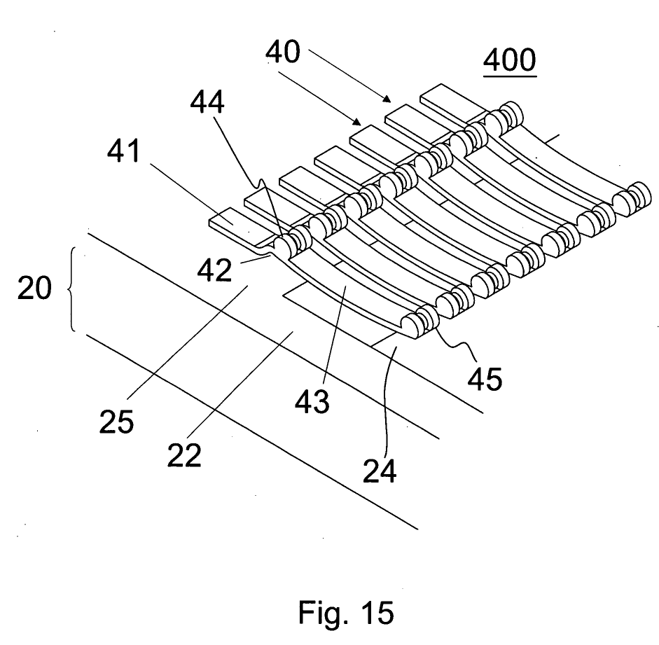

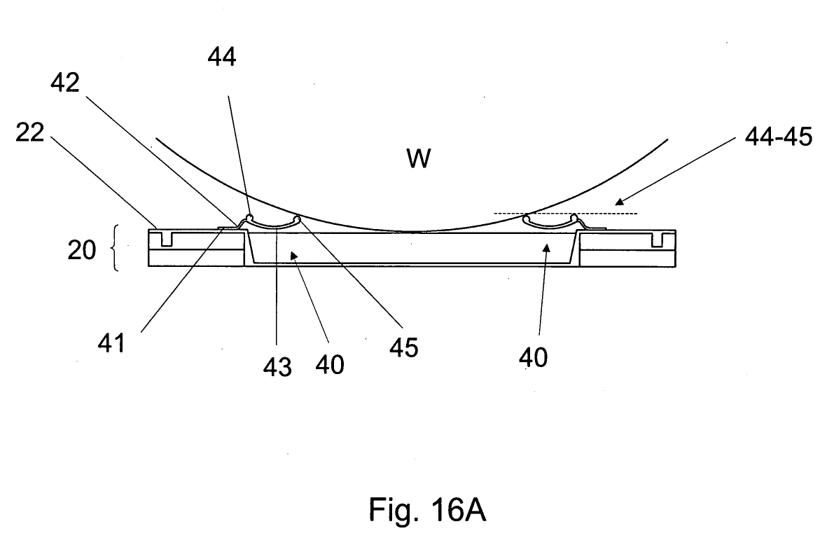

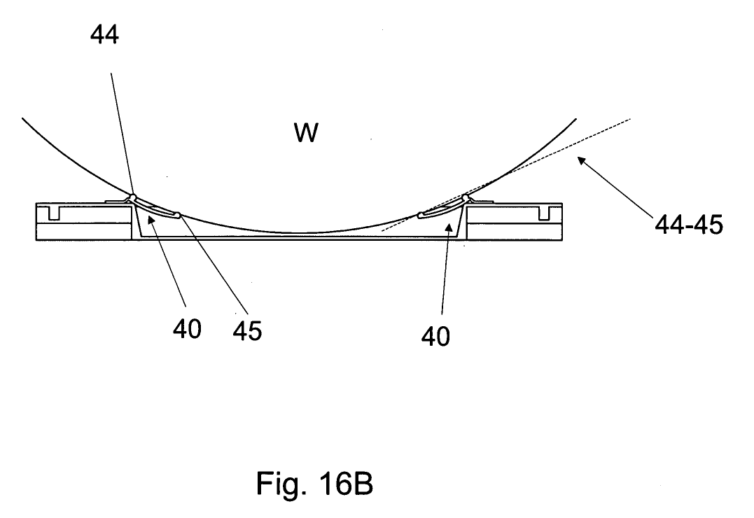

Secondly, referring to FIG. 14, which is a view of another wafer container of the present invention. The wafer container is the same as the wafer container as shown in FIG. 9 and includes a container body 10 and a door 20. The difference lies in that the wafer restraint module 400 fixed on two sides of the recess 24 of the inner surface 22 of the door 20 is different from the wafer restraint module 30. As shown in FIG. 15A and FIG. 16A, the wafer restraint module 400 on two sides of the recess 24 is formed by a plurality of wafer restraint components 40 with a space at interval, and each wafer restraint component 40 is aligned with a corresponding wafer restraint module 40 of the wafer restraint module 400 that is located on the other side of the recess 24. Each wafer restraint component 40 includes a base portion 41 that is fixed on the inner surface 22 of the door 20, and one sidewall of the base portion 41 is located adjacent to the recess 24. The sidewall of base portion 41 described above is extended toward the opening of the container body 10 to form a curve portion 42 and turned to the central portion of the recess 24 to form a plurality of bent arms 43. The plurality of bent arms 43 are disposed on two side of the top of the recess 24, and the cross of the bent arm 43 and the curve portion 42 includes a first contact head 44, and the free-end of the bent arm 43 includes a second contact head 45 thereon. As shown in FIG. 16A, each wafer restraint component 40 is an elastic integrated structure (for example: thermal-elastic plastic). When the door 20 and the container body 10 are about to be joined, the connected line (44-45) between the first contact head 44 and the second contact head 45 of the wafer restraint component 40 is parallel to the inner surface 22 of the door 20. Meanwhile, the wafer first contacts the second contact head 45 to deform the curve portion 42 to lever the bent arm 43, so as another contact head of the bent art 43, i.e. the first contact head 44, will contact the wafer in sequence. Meanwhile, as shown in FIG. 16B, the door 20 is sealed with the container body 10, and an included angle is formed between the connected line (44-45) of the first contact head 44 and the second contact head 45 of the wafer restraint component 40 and the inner surface 22 of the door 20. Obviously, each wafer restraint component 40 contacts the wafer with two contact heads for the wafer to be sustained and also be restricted from moving toward the opening of the wafer container. The tiny dust particles that are generated due to vibration during transportation of wafers can thus be reduced. In addition, the wafer can also effectively sink into the recess 24 for reduced the size of the wafer container.

The curve portion 42 of the wafer restraint component 40 is an elastic structure (for example: thermal-elastic plastic) with a bent angle. Thus, in the sealing procedure, when the door 20 and the container body 10 go from the status of not closed to the status of closed, the bent angle would be changed, and the first contact head 44 and the second contact head 45 are made to contact the wafer sequentially. Furthermore, the bent portion 42 and the bent arm 43 can be made of two different materials, such as plastic with different hardness which can generate larger deformation for the curve portion 42 and the bent arm 43 would not easily deform. The first contact head 44 and the second contact head 45 include a recess respectively, so as the wafer can sink into the recess to avoid up and down movement of the wafer. Moreover, the plurality of wafer restraint components 40 can form a base portion, wherein the base portion is firmly disposed on the inner surface 22 of the door 20. Certainly, the plurality of wafer restraint components 40 can also be integrated with the inner surface 22 of the door 20 to reduce the manufacturing cost.

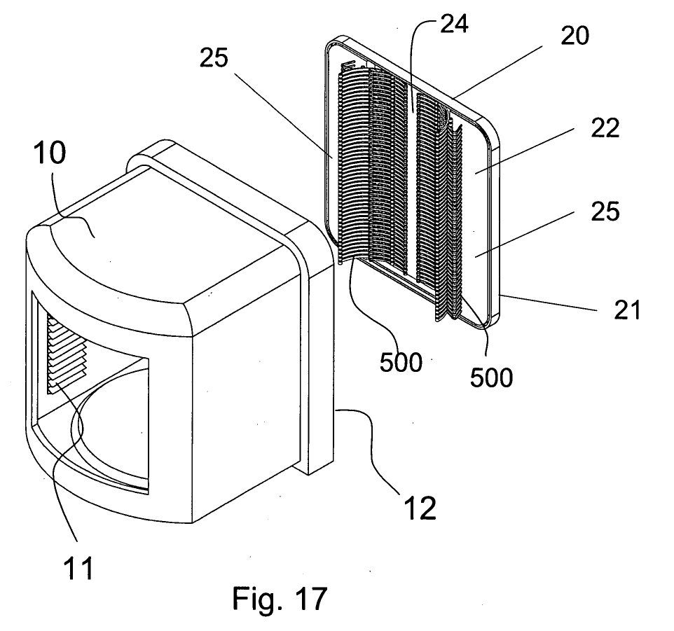

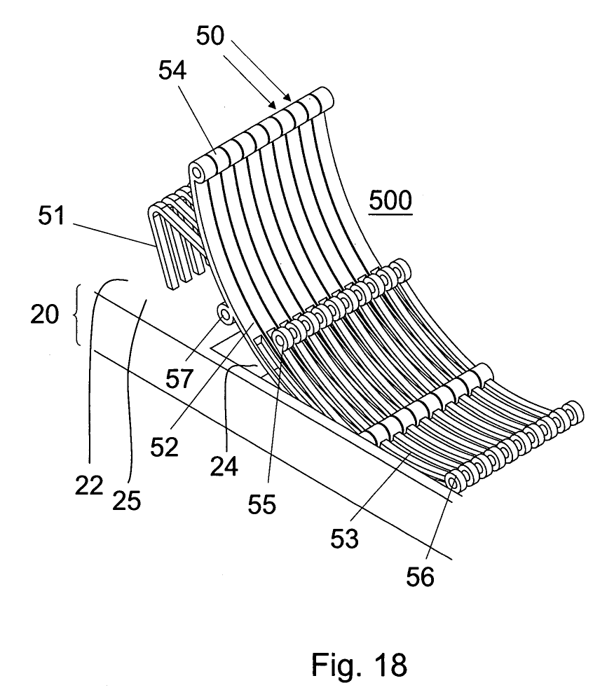

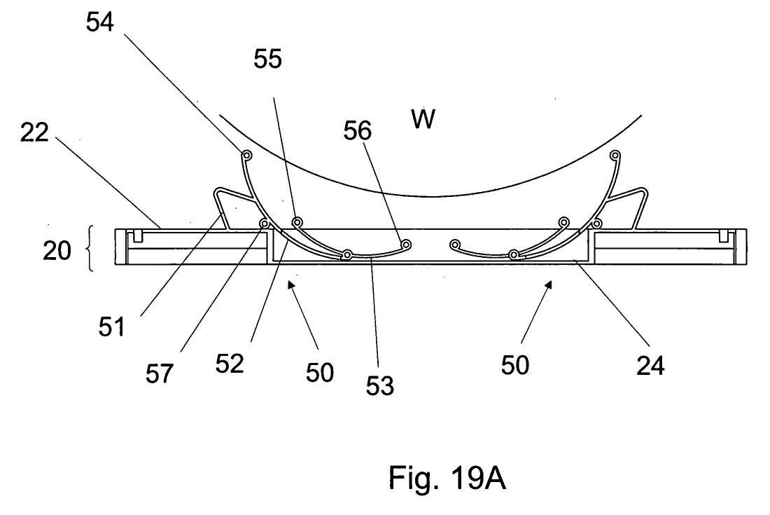

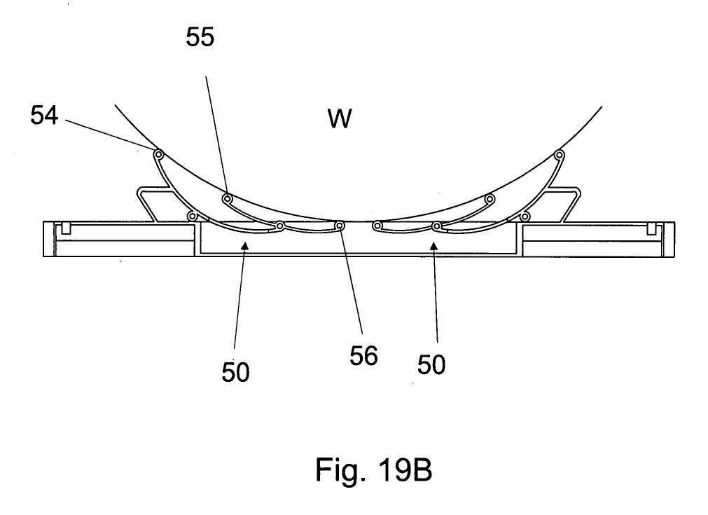

Then, referring to FIG. 17, which is a view of still another wafer container of the present invention. This front opening unified pod (FOUP) is similar to the wafer container as shown in FIG. 14 in that it includes a container body 10 and a door 20, yet different in that each of the wafer restraint modules 500 located on two sides of the recess 24 of the inner surface 22 of the door 20 includes three contact heads, as shown in FIG. 18 and FIG. 19A. The wafer restraint modules 500 on the two sides of recess 24 are composed of the plurality of wafer restraint components 50 in arrangement. Each wafer restraint component 50 is aligned with the corresponding wafer restraint component 50 on the wafer restraint modules 500 on the other side of the recess 24, wherein each wafer restraint component 50 includes a base portion 51. One end of the base portion 51 is fixed on the inner surface 22 of the door 20, and another end is connected to a first bent arm 52, the first bent arm 52 including two free-ends. A first contact head 54 is formed at one of the two free-ends that is located farther from the central part of the recess 24; another free-end adjacent to the central part of the recess 24 further contacts the second bent arm 53; and the second bent arm 53 further includes a second contact head 55 and a third contact head 56.

The base potion 51 of the wafer restraint component 50 is an elastic structure (for example: thermal-elastic plastic structure) and includes a bent portion. Therefore when the door 20 is not yet joined with or about to be joined with the container body 10, the second bent arm 53 of the wafer restraint component 50 is horizontally attached or slightly suspended to the surface of or above the recess 24. Thus, the wafer is first contacted by the first contact head 54, and during the contact, the base portion 51 is deformed, and thus the included angle of the bent is changed and levered the first bent arm 52 and the second bent arm 53, which in turn make the second contact head 55 and the third contact head 56 on the second bent arm 53 contact the wafer. Meanwhile, as showing FIG. 19B, when the door 20 seals the container body 10, the second bent arm 53 is levered by the base portion 51 and the first bent arm 52 and driven far away from the surface of the recess 24. Thus, the first contact head 54, the second contact head 55, and the third contact head 56 of the wafer restraint component contact the wafer. Obviously, each wafer restraint component 50 provides three contact heads for supporting the wafer to more firmly restrict the wafer from moving toward the center of the opening or two sides of the opening of the wafer container. Certainly, in the present embodiment, a pivot 57 can be alternatively provided between the two free-ends of the first bent arm 52 and on one side of the inner surface 22 of the door 20, wherein the pivot 57 is fixed on the inner surface 22 of door 20. Thus, when the base portion 51 is deformed or the angle of the bent is changed, the first bent arm 52 and second bent arm 53 can be more firmly levered so that the first contact head 54, the second contact head 55, and the third contact head 56 can attach tightly to the wafer.

And as the abovementioned two embodiments of contact head, each of the plurality of wafer restraint components 50 can be an elastic integrated structure (for example: thermal-elastic plastic structure). The base portion 51 and the first bent arm 52 or second bent arm 53 can also be made of different materials or different elastic structure (for example, thermal-elastic structure), such as plastic with different hardness. Thus, bent arms would not be deformed easily due to the deformation of the base portion 51. Alternatively, the first contact head 54, the second contact head 55, and the third contact head 56 can include a recess so as the wafer is sunk into the recess to restrict the wafer from moving up and down. The plurality of wafer restraint components 50 as described above can also be formed on a base portion, and the base portion is firmly disposed on the inner surface 22 of the door 20. Alternatively, the plurality of wafer restraint components 50 are integrated with the inner surface 22 of the door 20.

Furthermore, the inner surface 22 of door 20 of the present invention can be a plane surface without recess; at least a latch component 60 can be disposed between inner surface 22 and outer surface 21, and a latch component 60 is disposed in one preferred embodiment. The latch component 60 is the same as what is described in the aforementioned embodiment so will not be described in detail. In addition, in order for the plurality of wafers in the container body 10 can be fixed when the door 20 closes the container body 10, thus at least a restraint module can be disposed on inner surface 22 of above-mentioned plane surface or near the central area of above-mentioned plane surface. And the structure or the form of this restraint module is not limited in the present invention, therefore structures such as above-mentioned restraint module 30, restraint module 400, restraint module 500, or other similar structures can all be included in the present invention. Similarly, the restraint module is the same as what is described in the aforementioned embodiment so the specifics of the structure will not be described in detail.

Obviously, when driven by oval cam 62, the latch component 60 of the present invention can only make to-and-fro movement, moving forward and backward, and no shift will occur on the longitudinal (vertical) direction. Therefore, the latch component 60 of the present invention is a simpler design. When door 20 and container body of the present invention close, the plurality of wafer restraint components 50 fixed on inner surface 22 of door 20 directly contact wafers. A pair of moving bars 64 are driven by cam 62 to move toward the edge of door 20, which makes front plane 646 of moving bars 64 go through latch hole 27 on door 20 and be fastened in socket hole corresponding to latch hole 27 near the edge of opening of container body 10. Then, a purgation device can be disposed for purging seal element (not shown in Figure) between door 20 and container body 10 to isolate the interior of container body 10 from the exterior.

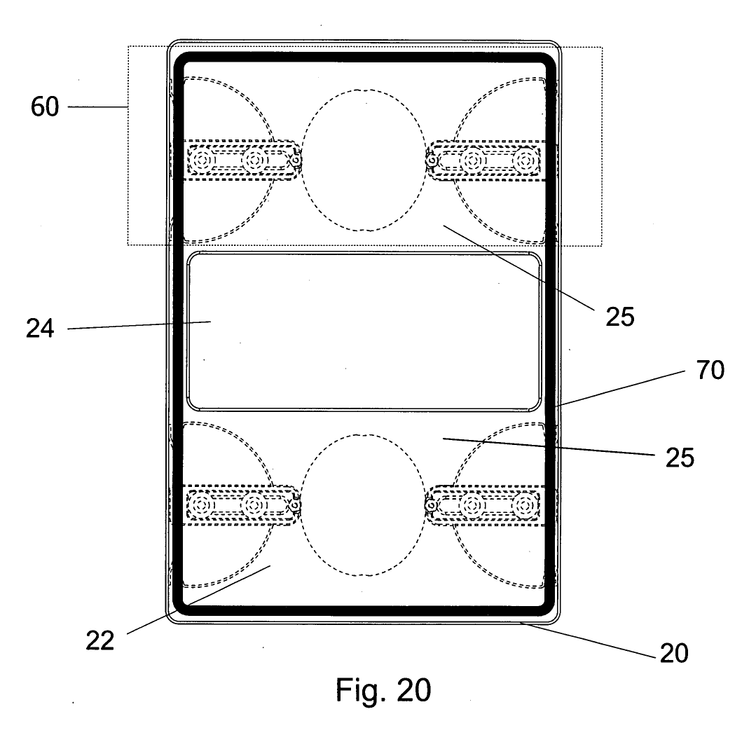

Then, referring to FIG. 20, which is a top view of a seal element disposed on the inner surface 22 of the door 20 of the present invention. As shown in FIG. 20, a recess 24 is formed in the central area of inner surface 22 of the door 20, and latch component 60 is disposed in the platform 25 on two sides of recess 24. Moreover, a seal element 70 is disposed around the rim of inner surface 22 of the door 20 and surrounds the door 20. In a preferred embodiment of the present invention, this seal element 70 is an inflatable sealing ring. The principle of purging this sealing is similar to that of purging a bicycle inner tube. Gas can be filled in through a purgation inlet (not shown in Figure) in order to purge the inflatable seal element 70. The condition of air tightness between the door 20 and the container body 10 can thus be achieved, and the wafers stored in the front opening unified pod (FOUP) can be prevented from being affected by the humidity of atmosphere. Obviously, the purgation inlet on the inflatable seal element 70 is fixed on the door 20. In addition, the inflatable seal element 70 in the present embodiment can be rubber element, and can also be springy element formed by polymer plastic material.

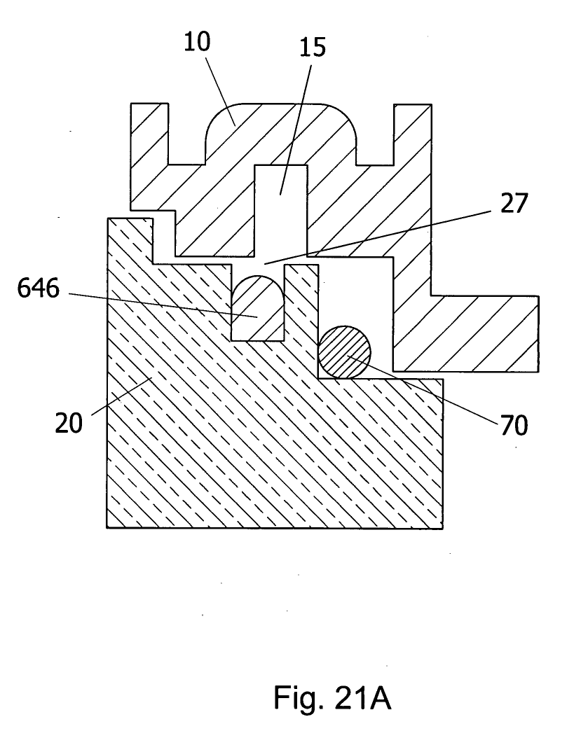

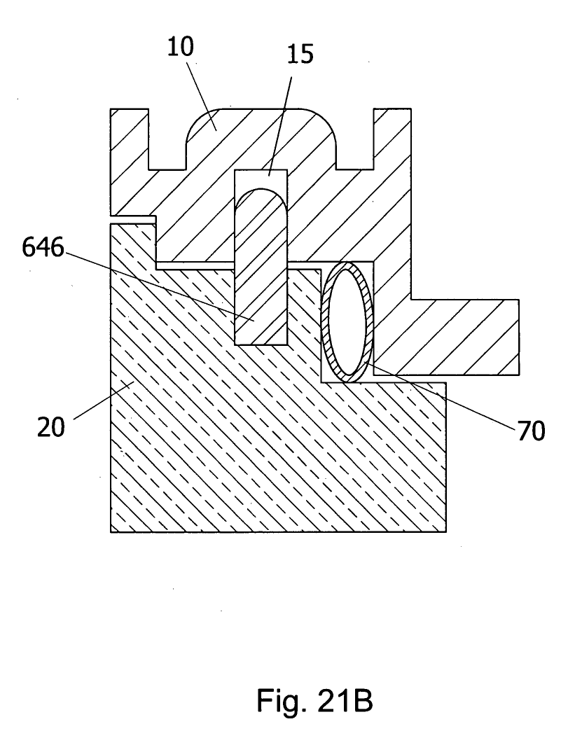

Then referring to FIG. 21A and FIG. 21B, which are cross-sectional views of part of sealing design as shown in above-mentioned FIG. 20 before and after air tightness is achieved. What is to be emphasized here is that in latch component 60 of the present invention disclosed in FIG. 5, oval cam 62 is used to drive the moving bars 64 to move to and fro on a single plane surface, and therefore when the door 20 is closed with the opening on container body 10, with the rotation of oval cam 62, the front plane bolts 646 of moving bars 64 are made to go through latch hole 27 on door 20 and be fastened to the socket hole 15 of container body 10 to achieve the locking effect. What is to be emphasized here is that in latch component 60 of the present invention disclosed in FIG. 5, oval cam 62 is used to drive the moving bars 64 to move to and fro on a single plane surface, and therefore when the door 20 is closed with the opening on container body 10, with the rotation of oval cam 62, the front plane bolts 646 of moving bars 64 are made to go through latch hole 27 on door 20 and be fastened on the container body 10 to achieve the locking effect. Obviously, although the container body 10 and the door 20 are already locked together at the period, air tightness between the container body 10 and the door 20 is not yet achieved. Thus, the seal element 70 of the present embodiment (FIG. 20, FIG. 21A, and FIG. 21B) can be used to achieve air tightness. Obviously, as the container body 10 and the door 20 are already locked together, uniform air tightness can be formed with the inflation pressure generated by purging the seal element 70 (as shown in FIG. 21B). And when it is needed to open the door 20, the pressure of seal element 70 can first be released and then the oval cam 62 is rotated for plane surface bolts 646 of moving bars 64 to depart from the container body 10.

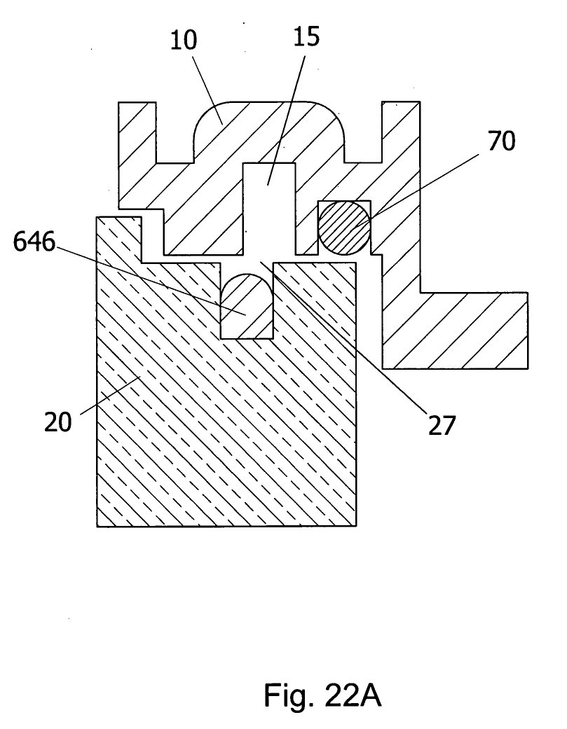

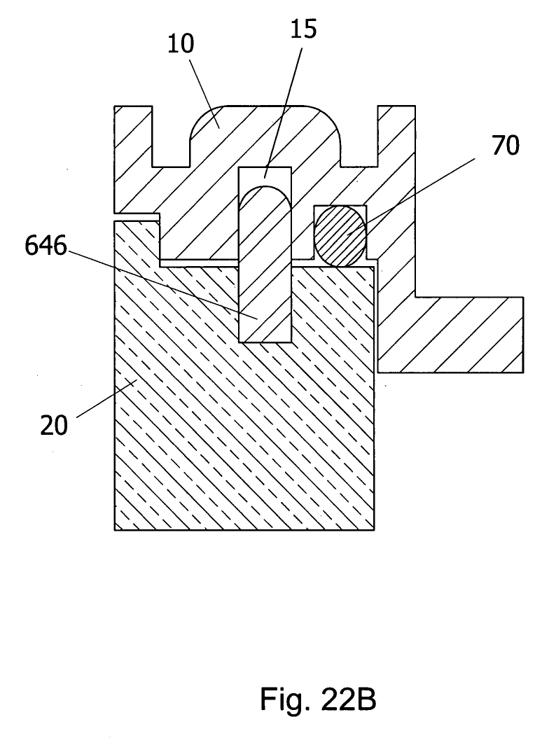

Then, referring to FIG. 22A and FIG. 22B, which are sectional views of part of another sealing design of front opening unified pod (FOUP) of the present invention before and after air tightness is achieved. The only difference between the present embodiment and the embodiment shown in FIG. 21A is that in the present embodiment, the inflatable seal element 70 can be set in the rim around the opening of the container body 10. When the container body 10 and the door 20 are locked together with the rotation of oval cam 62, air tightness is still not achieved between the container body 10 and the door 20; air tightness between the container body 10 and the door 20 is achieved only till the purging process of inflatable seal element 70 is completed (as shown in FIG. 22B). Similarly, when it is needed to open the door 20, the pressure of inflatable seal element 70 can first be released and then the oval cam 62 is rotated for plane surface bolts 646 of moving bars 64 to depart from the container body 10 and the door 20.

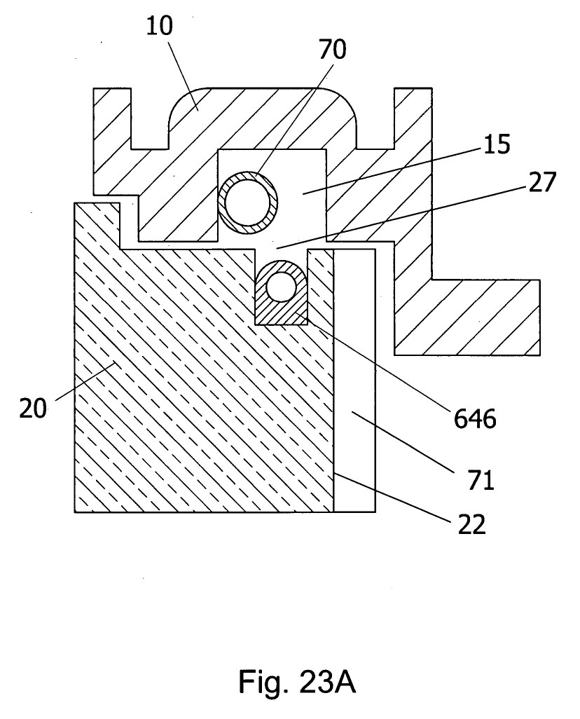

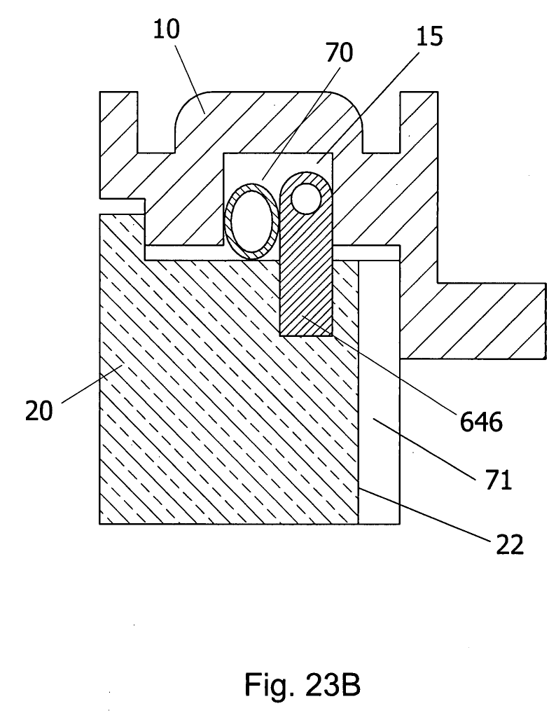

In addition, referring to FIG. 23A and FIG. 23B, which are sectional views of part of still another sealing design of front opening unified pod (FOUP) of the present invention before and after air tightness is achieved. The difference between the present embodiment and the embodiment shown in FIG. 22A is that in the present embodiment, the inflatable seal element 70 can be set in the socket hole 15 of the container body 10. The socket hole 15 corresponds to the latch hole 27 on the door 20 for allowing the physical plane surface 646 of the moving bars 64 to enter the latch hole 27 and the socket hole 15 when the oval cam 62 rotates. In addition to the different position of the inflatable seal element 70, a seal element 71 is further added in the present embodiment by being disposed in the surrounding area of the inner surface 22 of the door 20; the seal element 71 can be an O-ring or polymer material or rubber pad. Thus, as shown in FIG. 23B, when the physical plane surface 646 of moving bars 64 enters the latch hole 27 and the socket hole 15, the seal element 70 is purged in order to achieve air tightness between the door 20 and the container body 10 with the inflated and purged seal element 70 and to further press the door 20 toward the direction of the container body 10 by inflation, the seal element 71 on the door 20 and the container body 10 being thus closely joined with each other and effect of air tightness being doubled. Similarly, when it is needed to open the door 20, the pressure of inflatable seal element 70 can first be released and then the oval cam 62 is rotated for plane surface bolts 646 to depart from the container body 10.

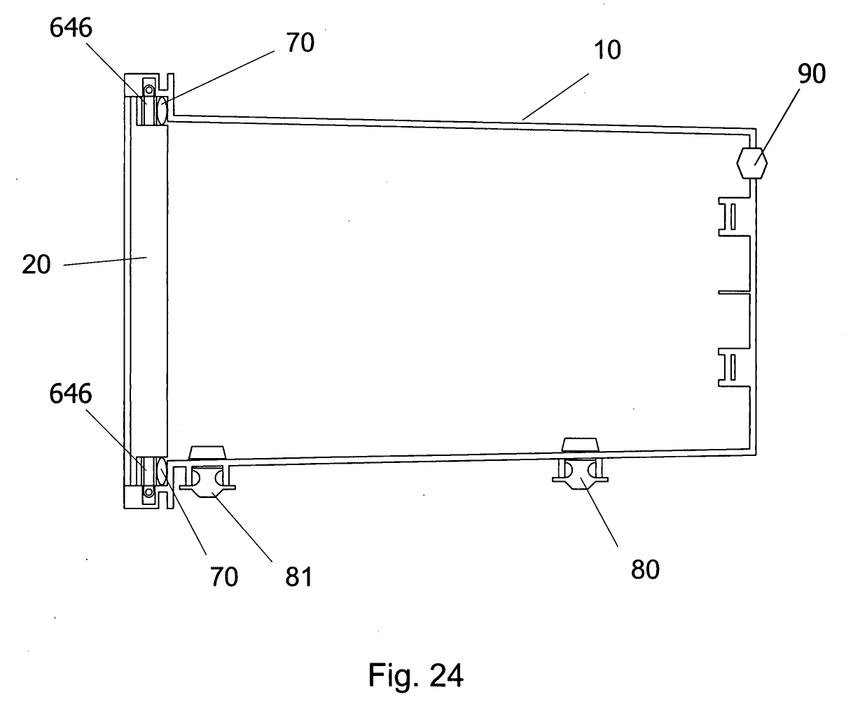

Referring then to FIG. 24, which is a cross-sectional view of front opening unified pod (FOUP) of the present invention when the door is closed and the seal element is purged. As shown in FIG. 24, when the door 20 closes the container body 10, the bolts 646 go through latch hole 27 on the door 20 and are fastened on the container body 10, and air tightness between the container body 10 and the door 20 is also achieved by the inflation of the seal element 70. In order to prevent the atmosphere outside the front opening unified pod (FOUP) from rapidly entering the container body 10 and thus causing pollution of wafers in the following process of opening the door 20, in another preferred embodiment of the present invention, at least a purgation valve 80 is further formed on the container body 10 for filling gas into the interior of the container body 10. Thus, when the door 20 closes the container body 10 and the air tightness between the container body 10 and the door 20 is achieved by the inflation of seal element 70, a purgation device (not shown in Figure) can be used to fill gas into the purgation valve 80 on the container body 10, filling in nitrogen or other inert gases for example, for forming air pressure higher than exterior atmosphere in the interior of container body 10 (i.e. forming so-called positive pressure). Thereafter, if the pressure of seal element 70 on the door 20 is released in order to diminish air tightness, since the air pressure in the container body 10 is higher than that of external atmosphere, air in the interior of the container body 10 will leak to the exterior and the external atmosphere can be prevented from filling into the container body 10.

And during the process in which positive pressure is formed inside the container body 10, in order to prevent the internal pressure from becoming too high and thus causing damage to container body 10 or wafers in the container body 10, a pressure release valve 90 can be further disposed on the container body 10 in the present invention, for example, on the back wall or sidewall of container body 10. Thus in the process in which positive pressure is formed, when the internal pressure of container body 10 is higher than a pre-set value, excessive pressure will be released from this pressure release valve 90 for a pre-set pressure to be maintained in the container body 10.

Furthermore, at least an exhaust valve 81 can be further disposed on the container body 10. When the above-mentioned purgation device fills gas in the purgation valve 80, an exhaust device (not shown in Figure) can be used at the same time to discharge trace amount of gas from the exhaust valve 81 for fully purging the whole wafer container more rapidly. And at least an exhaust valve 81 as described above can be disposed closer to the location of opening 12 of container body 10, and at least a purgation valve 80 can be disposed farther from the opening 12 of the container body 10; thus, particles inside the container body 10 can be cleanly and rapidly carried out of the container body 10 through the opening 12 or the exhaust valve 81 by the gas filled in.

While the invention has been described by way of examples and in terms of the preferred embodiments, it is to be understood that the invention is not limited to the disclosed embodiments. To the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A wafer container including a container body that having a plurality of slots therein for supporting a plurality of wafers and having an opening formed on a sidewall of said wafer container for exporting said plurality of wafers or importing said plurality of wafers, and a door with an outer surface and an inner surface, said door joining with said opening of said container body via said inner surface for protecting said plurality of wafers in said container body, the characteristic in that:
at least a latch component is disposed between said inner surface and said outer surface of said door, and an inflatable seal element is disposed around rim of said inner surface of said door.

2. The wafer container according to claim 1, wherein material of said inflatable seal element is selected from the group consisting of: rubber and polymer plastic material.

3. The wafer container according to claim 1, wherein said latch component includes an oval cam, a pair of moving bars contacting two ends of said oval cam, at least one roller disposed between said inner surface and said outer surface of said door and fixed in a slide groove of said moving bars, and a locating spring being an integral part of said moving bars.

4. The wafer container according to claim 3, wherein a locating roller is further disposed on one end of said moving bars.

5. The wafer container according to claim 3, wherein a plurality of locating grooves are further disposed on said oval cam.

6. The wafer container according to claim 1, wherein at least a restraint module is disposed on said inner surface of said door.

7. The wafer container according to claim 1, wherein two platforms are formed on two sides of said inner surface of said door and a recess is thus formed near the central area.

8. The wafer container according to claim 7, wherein at least a restraint module is disposed respectively on each of said two platforms.

9. The wafer container according to claim 1, wherein said container body further includes at least a purgation valve.

10. The wafer container according to claim 1, wherein said container body further includes at least an exhaust valve.

11. The wafer container according to claim 1, wherein said container body further includes at least a pressure release valve.

12. A wafer container including a container body that having a plurality of slots therein for supporting a plurality of wafers and having an opening formed on a sidewall of said wafer container for importing and exporting said plurality of wafers, and a door with an outer surface and an inner surface, said door joining with said opening of said container body via said inner surface for protecting said plurality of wafers in said container body, the characteristic in that:
at least a latch component is disposed between said inner surface and said outer surface of said door, and an inflatable seal element is disposed around the rim of said opening of said container body.

13. The wafer container according to claim 12, wherein material of said inflatable seal element is selected from the group consisting of: rubber and polymer plastic material.

14. The wafer container according to claim 12, wherein said latch component includes an oval cam, a pair of moving bars contacting two ends of said oval cam, at least one roller disposed between said inner surface and said outer surface of said door and fixed in a slide groove of said moving bars, and a locating spring being an integral part of said moving bars.

15. The wafer container according to claim 14, wherein a locating roller is further disposed on one end of said moving bars.

16. The wafer container according to claim 14, wherein a plurality of locating grooves are further disposed on said oval cam.

17. The wafer container according to claim 12, wherein at least a restraint module is disposed on said inner surface of said door.

18. The wafer container according to claim 12, wherein two platforms are formed on two sides of said inner surface of said door and a recess is thus formed near the central area.

19. The wafer container according to claim 18, wherein at least a restraint module is respectively disposed on each of said two platforms.

20. The wafer container according to claim 12, wherein said container body further includes at least a purgation valve.

21. The wafer container according to claim 12, wherein said container body further includes at least an exhaust valve.

22. The wafer container according to claim 12, wherein said container body further includes at least a pressure release valve.

23. A wafer container including a container body that having a plurality of slots therein for supporting a plurality of wafers and having an opening formed on a sidewall of said wafer container for importing and exporting said plurality of wafers, and a door with an outer surface and an inner surface, said door joining with said opening of said container body via said inner surface for protecting said plurality of wafers in said container body, the characteristic in that:
at least a latch component is disposed between said inner surface and said outer surface of said door, an inflatable seal element is disposed around the rim of said opening of said container body, and another seal element is disposed in surrounding area of said inner surface of said door.

24. The wafer container according to claim 23, wherein material of said inflatable seal element is selected from the group consisting of: rubber and polymer plastic material.

25. The wafer container according to claim 23, wherein said other seal element is an O-ring.

26. The wafer container according to claim 23, wherein said other seal element is a rubber pad.
